(19) United States
(12) Patent Application Publication
(10) Pub. No.: US 2026/0366146 A1
(43) Pub. Date: Nov. 19, 2026

(54) METHOD FOR SYNTHESIZING DIAMOND BY DISTRIBUTED MICROWAVE PLASMAS

(71) Applicants: CENTRE NATIONAL DE LA RECHERCHE SCIENTIFIQUE, Paris (FR); UNIV PARIS XIII PARIS-NORD VILLETANEUSE, Villetaneuse (FR)

(72) Inventors: Fabien BENEDIC, Argenteuil (FR); Chaimaa MAHI, Aubervilliers (FR); Ovidiu BRINZA, Deuil la Barre (FR); Corinne DULUARD-CURLEY, Antony (FR); Riadh ISSAOUI, Taverny (FR); Jocelyn ACHARD, Ermont (FR); Alexandre TALLAIRE, Palaiseau (FR)

(73) Assignees: CENTRE NATIONAL DE LA RECHERCHE SCIENTIFIQUE, Paris (FR); UNIV PARIS XIII PARIS-NORD VILLETANEUSE, Villetaneuse (FR)

(21) Appl. No.: 19/478,032

(22) PCT Filed: May 3, 2024
(86) PCT No.: PCT/EP2024/062304

§ 371 Date: Oct. 23, 2025

(30) Foreign Application Priority Data
May 4, 2023 (FR) FR2304479

(51) Int. Cl. C23C 16/27; H01J 37/32

(52) U.S. Cl. CPC C23C 16/274; H01J 37/32192; H01J 37/32449; H01J 2237/3321

(57) ABSTRACT

A method for synthesizing diamond by distributed microwave plasma, to a reaction chamber for implementing the method, to the substrate including a diamond layer obtained according to the method, to a device chosen from hard and protective coatings for cutting and perforating tools, glasses, optics, windows, scalpels, biocompatible coatings for implantable medical devices, intracerebral electrodes and electronic devices, sensors, components for power electronics, heat sinks for electronic and optoelectronic components, encapsulated electronic devices, quantum sensors including a substrate with a layer of diamond obtained according to the method.

The invention belongs to the field of diamond synthesis, and in particular its application in the field of protective coatings, biocompatible coatings and electronic devices comprising nanocrystalline, microcrystalline, polycrystalline and single-crystal diamond films.

The present invention relates to a method for synthesizing diamond by distributed microwave plasmas, to a reaction chamber for implementing the method and to a solid substrate comprising a diamond layer obtained according to the method according to the invention. The invention also relates to a device selected from hard and protective coatings for cutting and perforating tools, glasses, optics, windows, scalpels, biocompatible coatings for implantable medical devices such as prostheses, dental implants, intracerebral electrodes and electronic devices such as surface acoustic wave or guided acoustic wave devices, sensors, components for power electronics (diodes, transistors, metal-oxide-semiconductor field-effect transistors (MOSFETs), heat sinks for electronic and optoelectronic components, encapsulated electronic devices, quantum sensors (magnetometers) comprising a solid substrate that comprises a diamond layer (or film) obtained according to the method according to the invention.

### PRIOR ART

Diamond offers a combination of exceptional mechanical, electronic, thermal, quantum and optical properties. These properties offer a wealth of potential for industrial applications in a variety of fields. However, the properties of diamond depend crucially on the quality of the material and its origin.

As a result, natural crystals are of little interest for technological applications, due to their rarity, prohibitive cost, small size and the variability of their characteristics depending on their origin. The development of techniques allowing reproducible diamond synthesis and control of its characteristics is therefore essential.

The first method developed in the 1950s for diamond synthesis was the so-called high-pressure/high-temperature (HPHT) method, based on the conversion of carbon, mixed with a metal catalyst, into diamond, by recreating extreme pressure and temperature conditions identical to those produced by nature to form diamond. This technique can be used to synthesize diamond crystals, but although major progress has been made recently, it has the disadvantage that the crystal lattice contains chemical impurities from the metal solvents used, in addition to the incorporation of nitrogen, which is difficult to control, limiting its use essentially to mechanical applications.

Other synthesis methods were developed in the 1980s to better control the composition and purity of the diamond, while ensuring reproducibility of the method and offering the possibility of obtaining the material in the form of coatings. These include chemical vapor deposition (CVD) methods. The principle behind these methods is the activation of a gas phase, consisting mainly of the elements hydrogen and carbon, by an external energy source, to generate the radical species, such as methyl and atomic hydrogen, needed to build the crystalline structure of high-quality diamond.

Depending on the type of energy source used to activate the gas phase, there are two main types of CVD method for diamond synthesis.

The HFCVD (HF for “hot filament”) method synthesizes diamond using a set of metal filaments, usually tungsten, heated by Joule heating to very high temperatures. This method is inexpensive and allows diamond to be deposited on large surfaces with complex geometries at speeds of up to 20 μm.h⁻¹. However, the filament placed very close to the substrate can degrade, heavily contaminating the deposited films and causing inhomogeneity in temperature distribution along the filament. Another disadvantage of this method is the nature of the material making up the filament. The filament, which is sensitive to oxidation and prone to corrosion, limits the choice of gas mixtures that can be used. Finally, the activation temperature of the gas phase remains limited by the melting temperature of the element making up the filament, thus limiting the rate of dissociation of the gaseous species.

None of the above methods can therefore produce high-purity diamond films (i.e. free from graphite and/or other chemical impurities).

The second type of CVD method is based on chemical activation of the gas phase using a plasma source, in particular a microwave source (MPA-CVD for “microwave plasma assisted-CVD”). This is the most widely used technique for synthesizing diamond for applications other than mechanical and tribological ones. There are multiple configurations for microwave reactors, most of which use resonant cavities, i.e. cavities whose dimensions allow them to excite a particular electromagnetic mode. These reactors can produce diamond films of good crystal quality which are ultra-pure, doped or include color centers, but have a number of limitations. Prior art CVD methods use a resonant cavity with an antenna and a plasma that forms away from the antenna (e.g. 50 cm). The dimensions of the treated surface are limited by the size of the plasma, which in turn is limited, in resonant cavity reactors, by the frequency of the microwave used. For example, using a microwave frequency of 2.45 GHz allows diamond to be deposited homogeneously over an area with a maximum diameter of 2 to 3 inches, while using a microwave frequency of 915 MHz allows diamond to be deposited over an area with a maximum diameter of 4 to 6 inches. In the latter case, the microwave power that has be injected is very high (30 to 60 KW), which poses efficiency problems at industrial level (excessive power consumption). The substrate temperatures required for diamond growth are generally in excess of 600 °C, which precludes the use of heat-sensitive materials. The high reactivity of the plasma leads to high growth rates (>1 μm.h⁻¹), which does not allow perfectly controlled synthesis of diamond films with submicrometer thicknesses. Finally, the use of a resonant cavity does not allow the treatment of three-dimensional parts.

More recently, other microwave methods using linear antennas or surface waves have been developed to allow diamond synthesis on large surfaces (up to 30×30 cm²) and at low temperatures (to 90 °C). However, these methods have a number of disadvantages, including:
a) the impossibility of controlling the temperature of the substrate independently of other operating conditions;
b) the need to inject high microwave powers, up to 20 kW;
c) the very low growth rates of only a few nm.h⁻¹;
d) the limitation to the processing of planar substrates only;
e) the difficulty in adapting experimental devices to industrial ones, in order to enlarge the deposition surface;
f) the production of nanocrystalline diamond films only.

Thus, whichever of the known methods is chosen, they all have different limitations which may be related to the deposited surface, the nature of the diamond layer or its homogeneity. In addition, the geometry of the parts to be treated is a limitation in most known methods. Finally, the nature of the substrates that can be used is also sometimes restricted.

There is therefore a need to develop a method that overcomes these limitations, particularly with regard to the surface deposited, the geometry of the parts to be treated, the nature of the substrates that can be used and the microstructure of the diamond layer obtained. There is also a need for single-crystal diamond films, preferably on a large scale.

It is to the applicant's credit that they have developed a method for coating at least one solid substrate with a synthetic diamond coating. By virtue of the method according to the invention, the synthetic diamond coating is advantageously in single-crystal, polycrystalline, microcrystalline or nanocrystalline form, preferably single-crystal form. The coating corresponds to one or more layers of diamond.

A first subject of the invention is a method for coating at least one solid substrate with a synthetic diamond coating, comprising the steps of:
a) placing the at least one solid substrate on a substrate holder, inside a reaction chamber comprising a cavity;
b) injecting a gas mixture into the chamber;
c) ionizing (or forming a plasma from) the gas mixture by subjecting the gas mixture to a microwave electromagnetic field, the microwave frequency ranging from 300 MHz to 6 GHz; and
forming a diamond coating layer on the at least one solid substrate, characterized in that,
the gas mixture consists of methane, dihydrogen, a third gas comprising at least one oxygen atom, and optionally a gaseous precursor of a doping element or reactivity modifier of the gas phase,
the CH₄/H₂ volume ratio ranges from 0.1 to 10% (i.e. volume ratio from 0.001 to 0.1),
the third gas/CH₄ volume ratio ranges from 0.1 to 120% (i.e. volume ratio from 0.001 to 1.2),
the temperature of the solid substrate is regulated to a value in a range from 100 to 1000 °C during the step of forming the diamond coating layer,
the pressure inside the reaction enclosure (i.e. chamber) is maintained in a range from 10⁻² to 100 mbar,
the microwave electromagnetic field being generated by means of a set of microwave sources.

To the best of the applicant's knowledge, there is currently no method for forming a synthetic diamond coating on a surface of one or more diamond or non-diamond solid substrates with a dimension greater than or equal to 6 inches (dimension greater than 0.1016 m or 0.1524 m), in single-crystal, polycrystalline, microcrystalline or nanocrystalline form.

The invention thus relates to a method for the CVD synthesis of diamond using distributed microwave plasmas. The method according to the invention is a growth method that possesses great versatility, which is lacking in known synthesis method systems. The method according to the invention thus makes it possible to synthesize all forms of diamond, whether nano-, micro-, poly-or single-crystal, preferably nano-and single-crystal, and also to produce an intrinsic material, doped or including color centers, over a wide temperature range, i.e. either at low temperature from 100 to 400 °C, which makes synthesis on heat-sensitive solid substrates possible, or at high temperature from 400 to 1000 °C.

The presence of the third gas comprising at least one oxygen atom makes it possible to provide additional etching species in the plasma, which advantageously makes it possible to eliminate non-diamond phases (e.g. graphite, amorphous carbon, etc.).

In addition, the presence of the third gas is essential when single-crystal diamond is to be obtained.

Furthermore, while most known experimental devices only allow diamond coating on planar surfaces (or “planar substrates”), the method according to the invention is suitable for deposition on both planar and “three-dimensional” solid substrates.

The method according to the invention also makes it possible to homogeneously synthesize diamond films over large surfaces, with diameters that can be greater than or equal to 8 inches (i.e. greater than or equal to 0.2032 m), whereas most known methods are limited to diameters of 4 inches (i.e. 0.1016 m).

The preparation conditions used in the method according to the invention lead to low growth rates, from a few nm.h⁻¹, e.g. 5 nm.h⁻¹, to several hundred nm.h⁻¹, e.g. 200 nm.h⁻¹, depending on the conditions, which allows precise control of thicknesses when these need to be submicrometer in size. Growth rates can range from 5 to 200 nm.h⁻¹.

The device for implementing the method according to the invention is designed in such a way that the deposited thicknesses can be monitored in situ in real time using various optical techniques. Typically, the deposited thicknesses, per layer, can range from a few tens of nm, for example 30 nm, to multiple um, for example 4 μm. The deposited thickness can range from 30 nm to 4 μm. In this way, the solid substrate can be coated with one or more diamond layers, giving a thickness of layers ranging from 30 nm to 4 μm.

Since the device for implementing the method according to the invention is not a resonant cavity, the reaction chamber has no physical limitations in terms of dimensions. In this way, the number of microwave sources can be increased as much as necessary to increase the volume of the plasma, in particular its diameter and, consequently, the deposition area on the solid substrate, without modifying the original reactor design. The geometry, chamber dimensions (height, diameter), openings (windows, doors), shape, position and dimensions of the substrate holder and solid substrate have no impact on the coupling of the electromagnetic wave to the plasma, which takes place directly at the end of each microwave source, thereby reducing constraints compared with resonant cavities. In other words, the cavity of the reaction chamber in which the coating method according to the invention is implemented is a non-resonant cavity. The cavity is therefore not configured to excite a particular electromagnetic mode. By virtue of this non-resonant cavity, low growth rates can be achieved, allowing homogeneous deposition.

The coupling of the electromagnetic wave to the plasma takes place directly at the end of each microwave source. The microwave sources are thus preferably positioned so that they have one end located at the level of the cavity. This makes it possible to use a non-resonant cavity.

The device (reaction chamber or enclosure) according to the invention can also be placed within a resonant cavity. This embodiment allows two excitation sources (two types of plasma) to be used:
1) the microwave point sources of the method and device according to the invention, thus allowing low growth rates, and
2) coupling using the resonant cavity to generate a high-energy plasma, allowing high growth rates as in conventional reactors.

It is thus possible, in a device according to the invention (i.e. a reaction chamber or enclosure comprising a non-resonant cavity) placed within a resonant cavity, to grow an intrinsic or doped film several tens of um thick in resonant mode, and then to make a layer according to the method according to the invention (for example delta-doped with nitrogen to create NV centers, or an encapsulation layer), to a small thickness (from 10 to 100 nm) in distributed plasma mode.

The method according to the invention allows homogeneous deposition of the diamond layer. What is meant by “homogeneous deposition” is deposition whose characteristics such as thickness, purity, grain size and texture do not vary by more than 10% over the entire area of the sample, so that the nano-, micro-, poly-or single-crystal nature remains unchanged over the entire sample. When the three-dimensional solid substrate has geometric patterns on its surface, such as studs, pillars, grooves, etch pits or electrodes, with lateral dimensions and/or depths ranging from 100 nm to 5 cm, synthesis is performed conformally, i.e. the deposit takes the shape of the geometric patterns.

In the present invention, nanocrystalline diamond means diamond in the form of particles with an average size ranging from about 5 to 50 nm, and preferably from about 15 to 20 nm.

In the present invention, microcrystalline diamond means diamond in the form of particles with an average size ranging from about 51 nm to 1 μm, and preferably from about 500 nm to 1 μm.

Diamond particle size can be determined by techniques well known to a person skilled in the art, preferably by transmission electron microscopy or X-ray diffraction.

In the present invention, polycrystalline diamond means diamond in the form of multiple crystallites and, as commonly understood, diamond in the form of particles with an average size greater than 1 μm.

In the present invention, single-crystal diamond means diamond in the form of a single crystal.

The single-or polycrystalline nature of the diamond can be determined by transmission electron microscopy.

According to step a) of the method according to the invention, at least one solid substrate is placed on a substrate holder inside a reaction chamber. The solid substrate can be placed manually or by an automated method using a motor-driven arm or rod.

Advantageously, the at least one solid substrate can be diamond or non-diamond, and preferably diamond. A solid diamond substrate is particularly useful for obtaining single-crystal diamond.

The solid substrate can be planar or three-dimensional. A planar solid substrate is defined as an object where one of its dimensions (width, length or height) is significantly smaller, by at least a factor of 10, than the other two dimensions (width, length or height). When there are multiple solid substrates, they may be identical or different. These can be planar solid substrates 8 inches in diameter or larger (i.e. 0.2032 m in diameter or larger), solid substrates of complex (three-dimensional) shape up to several centimeters in height, or even multiple solid substrates, planar or three-dimensional, arranged simultaneously on the substrate holder, provided their lateral dimensions allow this.

Advantageously, the at least one solid substrate can be composite or non-composite. Preferably, the solid substrate is composed of silicon, diamond, refractory metal, such as iridium, or derivatives thereof such as alloys, oxides or nitrides of said refractory metal, transition metal, such as titanium, or derivatives thereof such as alloys (e.g. titanium-based alloy such as TA6V), oxides or nitrides of said transition metal, stainless steel, a superalloy, a cemented carbide, a polymer, a ceramic, glass, an oxide (e.g. fused silica or alumina), semiconductor selected from the semiconductors of columns III-V and II-VI of the periodic table, a piezoelectric material, a nitride, a carbide, a sulfide, a silicide or a mixture thereof. Particularly preferably, the solid substrate is composed of diamond, refractory metal, such as iridium, and derivatives thereof such as alloys, oxides or nitrides of said refractory metal, transition metal, such as titanium, and derivatives thereof such as alloys (e.g. titanium-based alloy such as TA6V), oxides or nitrides, stainless steel, a superalloy, a cemented carbide, a polymer, a ceramic, glass, oxide (e.g. fused silica or alumina), semiconductor selected from the semiconductors of columns III-V or II-VI of the periodic table, a piezoelectric material, a nitride, a carbide, a sulfide, a silicide or a mixture thereof; and more particularly preferably, the solid substrate is composed of diamond.

Advantageously, the thermal contact between the at least one solid substrate and the substrate holder is preferably homogeneous over the entire contact surface between the at least one solid substrate and the substrate holder. The surface of the substrate holder can thus be adapted to the surface of the solid substrate with which it is intended to be in contact. What is meant by “contact surface” is the percentage of the face of the solid substrate that is in direct contact with the substrate holder on which the solid substrate rests. Ideally, this percentage is 100%. If the solid substrate is wavy or has a special shape, the shape of the substrate holder must be adapted to the solid substrate. Alternatively, a substance may be used to ensure contact between the solid substrate and the substrate holder, provided the dimensional differences between the solid substrate and the substrate holder (in terms of the contact surface) are not too great, e.g. thermal paste.

Advantageously, the substrate holder can be made of molybdenum or inconel or be diamond-coated. Preferably, the substrate holder is electrically isolated from the cavity of the reaction chamber. The substrate holder is preferably biased. In particular, the substrate holder can be provided with a biasing system whereby a voltage is applied to it via a metal conductor (rod, electric wire, coaxial cable, etc.), with the reaction chamber or one or more metal parts arranged above the solid substrate acting as counter-electrodes. Biasing can be DC, pulsed DC, AC (50 Hz), RF (13.56 MHz), low-frequency or high-frequency in the 1 Hz to 1 MHz range, in various periodic patterns (pulses or sawtooth, for example).

Advantageously, the system for biasing the substrate holder provides an additional degree of freedom compared with known microwave methods by assisting the growth stages, in particular germination, cleaning, etching, ion implantation, doping or generation of gaps in the deposits, by means of ion bombardment. This aspect is advantageous, either to ensure good adhesion of the diamond film to the solid substrate, or to promote doping or the formation of color centers involving vacancies (NV, SiV, GeV, or SnV centers).

In this way, the biasing system provides advantageous assistance by ion bombardment, on top of the microwave plasma generated by the elementary microwave sources:
diamond germination, i.e. the agglomeration of carbon atoms to form nuclei (seeds) which grow to form isolated crystals on the surface of non-diamond solid substrates, generally in the presence of excess carbon precursors in the gas phase;
cleaning of the solid substrate prior to diamond synthesis, advantageously using plasmas of gas mixtures containing hydrogen, argon or oxygen atoms;
etching of the solid substrate in order, for example, to remove the native oxide layer from solid silicon substrates or to reveal etch pits on the surface of solid diamond substrates, advantageously using plasmas of gas mixtures containing hydrogen, argon or oxygen atoms, or halogenated precursors containing atoms such as chlorine or fluorine;
etching diamond deposits, in particular to reduce their thickness, using plasmas of gas mixtures containing hydrogen atoms, noble gases such as argon or krypton, oxygen or halogenated precursors containing atoms such as chlorine or fluorine;
the implantation of atoms on the surface of certain solid substrates, in particular carbon, generally in the presence of an excess of carbon precursors in the gas phase, in order to create a carbide-type conversion layer intended to promote adhesion of the diamond film to the solid substrate;
doping during growth with other atoms (boron, phosphorus, silicon, nitrogen, tin, etc.) which may modify the electronic, optical and quantum characteristics of the deposited diamond in particular;
the generation of carbon vacancies which, combined with the presence of substitute atoms such as nitrogen, silicon, germanium or tin, create color centers involving vacancies (NV, SiV, GeV or SnV centers, for example).

Advantageously, the substrate holder can be fitted with a vertical translation system for adjusting the distance to the plane of the sources, said plane being defined by the array of sources and being parallel to the surface of the substrate holder. The substrate holder can be equipped with a rotation system, for example to optimize the homogeneity of deposition of the diamond layer over the entire surface of the solid substrate exposed to the plasma. This feature is particularly useful for three-dimensional parts, some of the sides of which may be more difficult for the plasma to access. The substrate holder can be fitted with a heating/cooling system to regulate the temperature of the solid substrate during the process. This temperature control can be carried out independently of the operating conditions (gas pressure, gas mixture, gas flow rate, microwave power applied to the sources, bias voltage/power). Advantageously, the temperature of the solid substrate is regulated to a value in a range from 100 to 1000 °C during the step of forming the diamond coating layer, preferably from 600 to 1000 °C and even more preferably 800 °C. The temperature of the solid substrate is regulated, i.e. the at least one solid substrate is preferably heated, cooled or maintained at temperature, by convection and/or thermal conduction through the substrate holder.

The various diamond microstructures that can be obtained by the method according to the invention can be obtained in the following temperature ranges:
from 100 to 400 °C: nanocrystalline,
from 400 to 600 °C: microcrystalline,
from 600 to 800 °C: polycrystalline on non-diamond solid substrate, single-crystal on diamond solid substrate,
for a gas mixture composed of 96.4% H₂ by volume, 2.6% CH₄ by volume and 1% CO₂ by volume, a power of 187 W per source and at a distance of 10 cm from the sources.

According to one particularly preferred embodiment of the method of the invention, the method leads to a single-crystal synthetic diamond coating according to one or more of the following characteristics, and more preferably according to all of the following characteristics:
the solid substrate is a solid diamond substrate,
the temperature of the solid substrate ranges from 650 to 850 °C,
the pressure inside the reaction chamber ranges from 0.25 to 0.45 mbar,
the CH₄/H₂ volume ratio ranges from 0.1 to 4%,
the third gas/CH₄ volume ratio ranges from 40 to 120%,
a power ranging from 75 to 200 W per source,
the solid substrate being at a distance of 4 to 12 cm from the sources.

Advantageously, the method according to the invention can further comprise one or more steps of preparing the surface of the solid substrate. Two cases can be distinguished: when the solid substrate is made of diamond, or when it is not (i.e. when the solid substrate is made of a material other than diamond, as described in the invention). Thus, when the solid substrate is made of diamond, the method according to the invention can further comprise a step of preparing the surface of the solid substrate and optimizing thermal contact with the substrate holder, selected from chemical treatment with acid (aqua regia), cleaning with organic solvents (such as ethanol, acetone), drying, H₂/O₂ plasma etching and bonding to the substrate holder. When the solid substrate is not made of diamond, the method according to the invention can further comprise a step of cleaning with organic solvents (such as ethanol, acetone), abrasion or spin or dip coating using a solution containing diamond grains of a size ranging from a few nm to a few tens of um in suspension, drying, and bonding to the substrate holder.

According to step b) of the method according to the invention, a gas mixture is injected into the reaction chamber. Step b) of injecting a gas mixture into the chamber can comprise three phases:
1) before the introduction of microwaves, for several minutes or even tens of minutes, the time to allow other growth parameters such as the temperature of the solid substrate or pressure to stabilize,
2) the entire duration of microwave injection (or application), which corresponds to the diamond growth phase. This injection (or application) is generally continuous, but the proportions of the gas mixture can be modified during this stage in order to modify the characteristics of the deposited diamond and thereby create a stack of diamond layers with different properties,
3) once the microwaves have been switched off, cooling the sample rapidly.

The composition of the gas mixture can be monitored using mass flowmeters. The gas mixture can consist of methane, dihydrogen and a third gas comprising at least one oxygen atom. What is meant by a “third gas comprising an oxygen atom” is a gas preferably selected from CO₂, CO, O₂ and mixtures thereof. The gas mixture can consist of methane, dihydrogen, a third gas comprising at least one oxygen atom and, optionally, a gaseous precursor of a doping element or reactivity modifier of the gas phase (in particular by modifying the thermal conductivity of the gas mixture). For example, the thermal conductivity of the plasma can be modified by adding argon to the gas mixture in place of hydrogen, and varying the [Ar]/[H₂] ratio. This modification is liable to change the temperature of the gas and consequently its reactivity. For example, an increase in the [Ar]/[H₂] ratio leads to a decrease in the thermal conductivity of the plasma and, consequently, to an increase in the temperature of the gas which is liable to promote radical chemical reactions within the gas phase. The precursor or modifier can preferably be a gas selected from N₂, N₂O, NH₃, B₂H₆, BBr₃, B(CH₃)₃, PH₃, PBr₃, SiH₄, GeH₄, SnH₄, Ar and He. The various gases making up the gas mixture are pre-mixed before being introduced into the reaction chamber. The gas mixture is introduced into the reaction chamber through one or more injectors (ports), the diameters of which may be the same or different and can be adjusted in order to modify and control the flow rate of the gas mixture through each injector (port) independently of the other injectors.

Gases comprising nitrogen, such as N₂, N₂O and NH₃, as precursors or modifiers, make it possible to incorporate nitrogen atoms into the diamond layer which, combined with carbon vacancies (NV centers), have a spin state that can be read and optically manipulated at room temperature, giving them properties suitable for the design of quantum sensors. Gases comprising a Group XIV element as a precursor or modifier, such as SiH₄, GeH₄ and SnH₄, can incorporate Group XIV atoms such as Si, Ge and Sn, respectively, which, combined with carbon vacancies, create SiV, GeV and SnV color centers, respectively, giving them properties comparable to NV centers. Gases such as B₂H₆, BBr₃, B(CH₃)₃ or PH₃, PBr₃, as a precursor or modifier, make it possible to incorporate boron B and phosphorus P atoms, respectively, and obtain P-type (acceptor) and N-type (donor) doping, respectively. For example, a gas mixture made up of 96.4% H₂ by volume, 2.6% CH₄ by volume, 1% CO₂ by volume and 0.04% N₂ by volume produces a single-crystal diamond layer containing NV centers on a high-pressure/high-temperature (HPHT) solid diamond substrate. Considering the basic gas mixture made up of 96.4% H₂ by volume, 2.6% CH₄ by volume and 1% CO₂ by volume, and replacing part of the H₂ stream with argon (Ar) so as to obtain, for example, a gas composition of 46.4% H₂ by volume, 2.6% CH₄ by volume, 1% CO₂ by volume and 50% Ar by volume, the thermal conductivity of the gas mixture is halved, resulting in a rise in gas temperature and consequent change in the reaction processes within the plasma.

Advantageously, in the gas mixture, the CH₄/H₂ volume ratio can be in the range from 0.1 to 10% (i.e. volume ratio from 0.001 to 0.1), preferably from 2 to 3% (i.e. volume ratio from 0.02 to 0.03).

Advantageously, in the gas mixture, the third gas/CH₄ volume ratio can be in a range from 0.1 to 120% (i.e. volume ratio from 0.001 to 1.2), preferably 40% to 120% (i.e. volume ratio from 0.4 to 1.2).

The ratio can be adapted according to the desired diamond microstructure. For example, a gas mixture consisting of 96.4% H₂ by volume, 2.6% CH₄ by volume and 1% CO₂ by volume allows the synthesis of nanocrystalline diamond at solid substrate temperatures ranging from 100 to 400 °C. At 750 °C, a gas mixture made up of 94.4% H₂ by volume, 2.6% CH₄ by volume and 3% O₂ by volume allows the synthesis of single-crystal diamond on HPHT solid diamond substrates. At 650 °C, the use of a gas mixture comprising 96.4% H 2 by volume, 2.6% CH 4 by volume and 1% CO 2 by volume leads to the formation of microcrystalline diamond.

Advantageously, in the gas mixture, the volume ratio of gaseous doping element precursor or reactivity modifier/CH₄ can be in the range from 0.001 to 10000% (i.e. volume ratio from 0.00001 to 100). Illustrations are given above.

According to step c) of the method according to the invention, the gas mixture is ionized (or transformed into plasma) by being subjected to a microwave electromagnetic field. Microwave frequencies can range from 300 MHz to 6 GHz. The frequency is preferably selected from 466 MHz, 915 MHz, 2.45 GHz and 5.8 GHz, 915 MHz and 2.45 GHz being the two standardized frequencies authorized for industrial applications. The microwave power can range from several watts to several hundred watts per source, and can be injected continuously (continuous mode) or discontinuously (pulsed mode) in a cyclic pattern (pulses, sinusoids, sawtooth or other), varying the pattern repetition frequency, average power, peak power and duty cycle in the case of pulses.

Advantageously, the microwaves are generated by microwave sources.

What is meant by “microwave source” is an electromagnetic coupling device (antenna), generally axisymmetric, consisting of a metal central core advantageously protected by an insulating refractory material, such as alumina, and featuring an impedance matching system. Microwave sources are described, for example, in patent application WO03/103003A1. The power of a microwave source can range from 1 W to 500 W, preferably 200 W. The invention uses a set of microwave sources. In other words, the number of microwave sources is greater than or equal to two. The plasma generated by a source is axisymmetric, and the area defined by the intersection between the plasma and a plane parallel to the plane of the sources (hatched area, FIG. 5) varies from 1 to 20 cm² depending on plasma gas pressure, microwave power and distance from the source. For a set of N coplanar sources d cm apart arranged in a square array, N being an integer greater than or equal to 4, the dimension of the plasma in a plane parallel to the source array (hatched area part 52 FIG. 5) is at least ((\sqrt{N}−1)×d)² cm².

Advantageously, the sources can be magnetized using permanent magnets. Magnetizing the sources traps the electrons in a static, axisymmetric dipolar magnetic field and imparts maximum energy to them via electron cyclotron resonance, generating dense, energetic plasmas that enhance chemical reactivity and thus the production of active species.

Advantageously, step c) can last from several minutes to several hours, or even tens of hours. Preferably, step c) is carried out for as long as necessary to obtain the desired diamond thickness, typically from 1 minute to 100 hours.

Advantageously, steps b) and c) are carried out simultaneously.

Advantageously, the microwave sources form a planar array of sources or have a three-dimensional configuration adapted to the geometry of the one or more solid substrates (FIGS. 1, 2 and 3). By optimizing growth conditions (pressure, microwave power, surface temperature and/or gas composition), plasma homogeneity (electron density and temperature, gas temperature, active species density) can be achieved over several centimeters perpendicular to the solid substrate and over several tens or even hundreds of centimeters, depending on the number of microwave sources, parallel to the solid substrate, which is ideal for homogeneous treatment of planar parts of large size and three-dimensional parts, without the need for a three-dimensional configuration of the sources.

Advantageously, the distance between the at least one solid substrate and a microwave source can be in a range from 0.1 cm to 15 cm, preferably 5 to 15 cm, even more preferably 10 cm. A person skilled in the art will be able to apply a distance determined by the desired microstructure of the diamond film. The further the substrate holder is from the sources, the more the microstructure obtained on non-diamond solid substrates changes from polycrystalline to nanocrystalline via microcrystalline. The distance mentioned corresponds to the shortest distance between the plane of the microwave sources and the surface of the solid substrate closest to the microwave sources (whether the solid substrate is planar or 3D). The surface of the solid substrate to be considered is the surface in contact with the plasma, i.e. the total surface of the solid substrate minus the surface of the substrate in contact with the substrate holder holding it.

Advantageously, when the method is implemented at low pressure, i.e. <1 mbar, the plasma is generated and maintained by applying microwave power of a few tens to a few hundreds of watts per source. At a distance of 5 to 12 cm, a few centimeters from the source plane, this plasma is perfectly homogeneous in the plane parallel to the source plane, and homogeneous over a few centimeters perpendicular to this plane. Depending on the number of sources used, this configuration makes it possible to obtain homogeneous diamond deposits over large areas, typically 8 inches in diameter or more (1 inch=0.254 m), allowing different configurations of solid substrates to be treated when placed on a substrate holder suitably located in relation to the sources. In this method, ionization of the gas mixture forms a diamond coating layer on the at least one solid substrate.

According to the method according to the invention, during the implementation of steps b) and c), the pressure inside the reaction chamber is maintained in a range from 10⁻² to 100 mbar, preferably from 5×10⁻² to 50 mbar, and even more preferably from 10⁻¹ to 1 mbar.

Advantageously, steps b) and c) can be repeated a number of iterations n, n being an integer greater than or equal to 2, preferably 2≤n≤10, so as to form a series of diamond coating layers on the solid substrate, the gas mixture being identical or different at each iteration.

Advantageously, the method according to the invention can further comprise a step d) of measuring the temperature of the solid substrate. The temperature can be measured by thermocouple or pyrometry. Particularly when treating three-dimensional solid substrates, where temperature homogeneity is important, this step allows deposits to be produced that are homogeneous in terms of thickness, microstructure and quality.

Advantageously, the method according to the invention can further comprise a step e) of in situ optical monitoring. Monitoring step e) can be carried out using an in situ optical monitoring system, preferably selected from among interference pyrometry, laser reflectance interferometry and spectroscopic reflectometry monitoring systems. This step makes it possible to measure the thickness and optical index of the growing diamond layer in real time, or to detect any changes occurring on the surface of the solid substrate (e.g. germination, etching, a change in topography and a change in composition).

Advantageously, steps d) and e) can be carried out simultaneously with steps a), b) and c), throughout the entire method according to the invention.

Another subject of the invention is a reaction chamber comprising:
a substrate holder, suitable for holding a solid substrate or set of planar or three-dimensional solid substrates,
a set of microwave sources and
optionally, optical ports.

The optical ports, microwave sources, substrate holder and solid substrate (planar or three-dimensional) are as defined in the invention.

Advantageously, the reaction chamber consists of a vacuum chamber with a set of microwave probes above it. The dimensions of the reaction chamber range from 25 liters for 16 sources to 100 liters for 36 sources. The microwave sources are preferably elementary plasma sources supplied by one or more microwave generators. The various sources can be arranged in a two-dimensional array (all sources coplanar) or in a three-dimensional configuration. The arrangement of the set of sources can be adapted by a person skilled in the art according to the one or more solid substrates to which the method is to be applied. These microwave sources can be magnetized or not magnetized.

Advantageously, the reaction chamber according to the invention can be arranged within a resonant cavity for exciting a particular electromagnetic mode. By means of suitable electromagnetic coupling, in addition to point microwave sources, two types of plasma can be triggered: a distributed microwave plasma with the advantages described above, offering in particular low growth rates, and a high-energy microwave plasma allowing high growth rates equivalent to conventional resonant cavity reactors. The invention also relates to a solid substrate comprising one or more diamond layers, obtained according to the method according to the invention.

The solid substrate is preferably as defined in the invention.

Advantageously, the solid substrate comprising one or more diamond layers, obtained according to the method according to the invention, can take various forms. The one or more diamond layers can be nanocrystalline, microcrystalline, polycrystalline or single-crystal, preferably single-crystal.

Depending on the nature of the gas mixture, the intrinsic properties of the diamond can be modified, for example by doping (e.g. with boron or phosphorus atoms) or including color centers (e.g. NV, GeV, SiV, SnV centers).

According to one particularly preferred embodiment of the invention, the one or more diamond layers deposited on the solid substrate are layers including NV centers.

The synthesis of nanocrystalline diamond films at low solid substrate temperatures (i.e. 100 to 400 °C) allows heat-sensitive materials to be treated. The synthesis of single-crystal diamond films is effective at high solid substrate temperatures (i.e. 600 to 1000 °C) on solid diamond substrates. The synthesis of nano-, micro-and polycrystalline diamond films on multiple planar or three-dimensional solid substrates arranged simultaneously on the substrate holder is made possible by the method according to the invention. The method also allows single-crystal diamond films to be synthesized on multiple planar solid diamond substrates arranged simultaneously on the substrate holder. The method according to the invention also allows very low growth rates, from a few nanometers (at low pressure <0.25 mbar, low power <75 W/source, low methane content <1%) to a few tens of nanometers per hour (at higher pressure >0.35 mbar, high power >180 W/source, high methane content >2%), allowing precise control of deposited thicknesses in the range from a few nanometers to a few micrometers.

According to one more particularly preferred embodiment of the invention, the one or more diamond layers deposited on the solid substrate are undoped single-crystal diamond layers or single-crystal diamond layers including NV centers.

The invention also relates to a device comprising a solid substrate obtained by the method according to the invention. Solid substrates coated with diamond films produced using the method according to the invention are used in particular in protective coatings for mechanical and optical engineering, biomedical devices, electronic and quantum devices.

Advantageously, the device comprising a solid substrate obtained by the method according to the invention can be selected from hard and protective coatings for cutting and perforating tools, glasses, optics, windows, scalpels, biocompatible coatings for implantable medical devices such as prostheses, dental implants, intracerebral electrodes and electronic devices such as surface acoustic wave or guided acoustic wave devices, sensors, components for power electronics (selected from diodes, transistors and MOSFETs), heat sinks for electronic and optoelectronic components, encapsulated electronic devices and quantum sensors such as ultrasensitive magnetometers.

Advantageously, when the one or more diamond layers deposited on the solid substrate is or are single-crystal, and in particular by virtue of their controlled thicknesses, the device comprising a solid substrate obtained by the method according to the invention can be selected from ultrasensitive quantum magnetometers. Indeed, this type of application requires color centers to be located near the surface at known depths with nanometer precision, which necessitates the creation of diamond layers incorporating nitrogen atoms and carbon vacancies from a few nanometers to a few tens of nanometers thick (delta-doping).

### BRIEF DESCRIPTION OF THE FIGURES

FIG. 1 shows an example of a reaction chamber 1 according to the invention, comprising a substrate holder 11, on which a planar solid substrate 12, a set of microwave sources 13 and optical ports 14 are arranged.

FIG. 2 shows an example of a reaction chamber 2 according to the invention, comprising a substrate holder 21, on which a three-dimensional solid substrate 22 (i.e. the entire surface of which is to be coated, with the exception of the parts in contact with the substrate holder) of cubic shape with 2 cm sides, a set of microwave sources 23 and optical ports 24 are arranged.

FIG. 3 shows an example of a reaction chamber 3 according to the invention, comprising a substrate holder 31, on which a set of solid substrates 32, a set of microwave sources 33 and optical ports 34 are arranged.

FIG. 4 shows (1) a substrate holder A with a diameter of 10 cm [size of this example], (2) the substrate holder A on which a large (10 cm diameter) planar solid substrate B is arranged, (3) the substrate holder A on which a plurality of 1 cm diameter planar solid substrates B are arranged, and (4) the substrate holder A on which a plurality of three-dimensional tungsten carbide drill bit substrates C, 6 mm in diameter and 6 cm in length, including 3 cm of covered helix, are arranged.

FIG. 5 shows the plasma generated by a single microwave source (1) according to the prior art and by a set of sources according to the invention arranged in a planar array (2). The hatched area represents the intersection between the volume of the plasma and a plane parallel to the plane of the sources.

FIG. 6 shows: 1. Surface of a nanocrystalline diamond film observed by scanning electron microscopy (SEM). 2. Surface of a microcrystalline diamond film observed by SEM. 3. Surface of a polycrystalline diamond film observed by SEM. 4. Surface of a single-crystal diamond film observed by SEM and transmission electron diffraction pattern showing the single-crystal nature of the deposit. 5. Photoluminescence spectra obtained with laser excitation at 473 nm of a nitrogen-doped single-crystal film before and after electron irradiation, with peaks at 575 nm (NV°) and 673 nm (NV⁻) demonstrating the presence of NV centers after irradiation.

The invention is further illustrated by the following non-limiting examples.

### Example 1: Implementation of the Method of the Invention

Provided is a reactor consisting of a cylindrical reaction chamber 30 cm high and 40 cm in diameter, topped by a set of 16 sources arranged in a 4×4 matrix. Also provided is a temperature-controlled 4-inch diameter circular substrate holder, arranged along the axis of this enclosure.

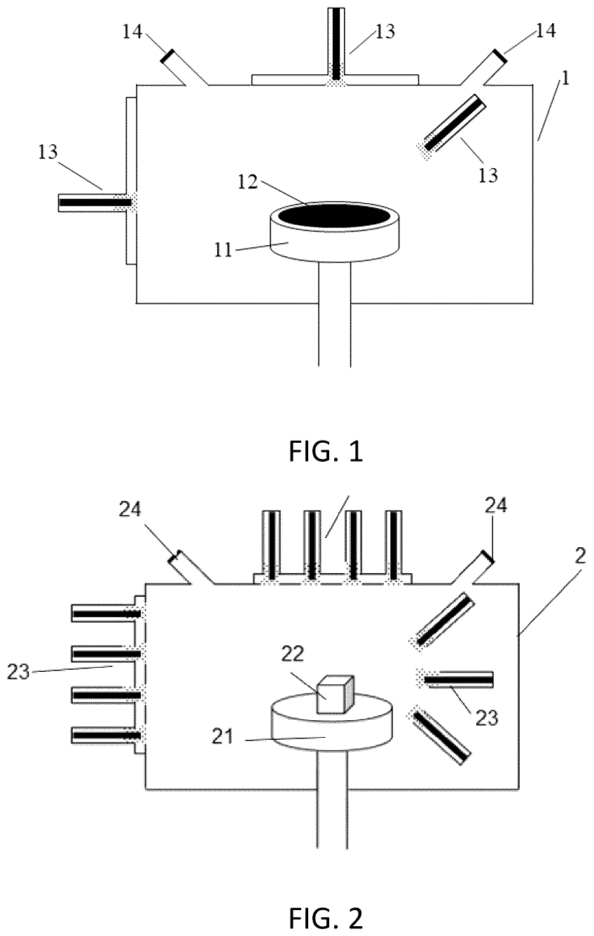

### 1. Synthesis of Nanocrystalline Diamond Films (FIG. 6-1)

Circular non-diamond solid silicon substrate, 4 inches in diameter and 0.5 mm thick.

Solid substrate preparation: spin coating or dip coating with diamond powder of average diameter 25 nm; abrasion with diamond powder of average diameter 30 μm. CH₄/H₂/CO₂ gas mixture. [CH₄]=2.6% and [CO₂]=1%. The gas mixture is injected at a flow rate of 50 SCCM (standard cubic centimeter per minute), for the duration of the synthesis.

Microwave power per source: 190 W.

Pressure: 0.35 mbar.

Substrate holder position (relative to microwave sources): 10 cm.

Solid substrate temperature: 250 °C.

Synthesis time: approx. 5 hours. Steps b) and c) are carried out simultaneously.

In example 1, the polycrystalline diamond obtained is nanocrystalline.

### 2. Synthesis of Microcrystalline Diamond Films (FIG. 6-2)

Circular non-diamond solid silicon substrate, 4 inches in diameter and 0.5 mm thick Solid substrate preparation: spin coating or dip coating with diamond powder of average diameter 25 nm; abrasion with diamond powder of average diameter 30 μm CH₄/H₂/CO₂ gas mixture. [CH₄]=2.6% and [CO₂]=1%. The gas mixture is injected at a flow rate of 50 SCCM for the duration of the synthesis.

Microwave power per source: 190 W.

Pressure: 0.25 mbar.

Substrate holder position (relative to microwave sources): 6 cm.

Solid substrate temperature: 400 °C.

Synthesis time: approx. 5 hours. Steps b) and c) are carried out simultaneously.

In example 2, the polycrystalline diamond obtained is microcrystalline.

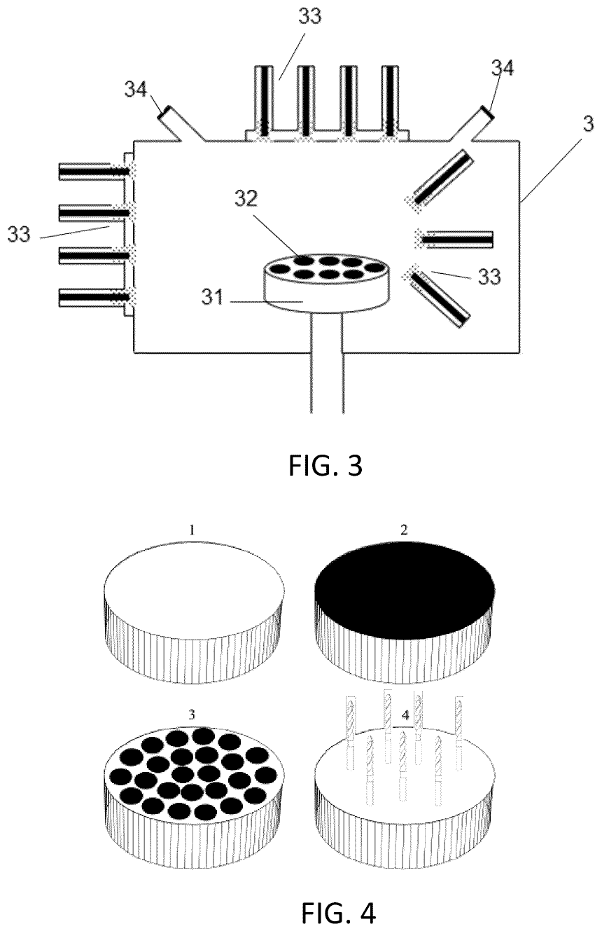

### 3. Synthesis of Polycrystalline Diamond Films (FIG. 6-3)

Circular non-diamond solid silicon substrate, 4 inches in diameter and 0.5 mm thick. Solid substrate preparation: spin coating or dip coating with diamond powder of average diameter 25 nm; abrasion with diamond powder of average diameter 30 μm. CH₄/H₂/CO₂ gas mixture. [CH₄]=2.6% and [CO₂]=1%. The gas mixture is injected at a flow rate of 50 SCCM for the duration of the synthesis.

Microwave power per source: 190 W.

### Pressure: 0.35 Mbar.

Substrate holder position (relative to microwave sources): 10 cm.

Solid substrate temperature: 650 °C.

Synthesis time: approx. 5 hours. Steps b) and c) are carried out simultaneously.

In this example 3, the polycrystalline diamond has a grain size greater than 1 μm.

### 4. Synthesis of Intrinsic Single-Crystal Diamond Films (FIG. 6-4)

High-pressure high-temperature (HPHT) Ib solid diamond substrate Solid substrate preparation: H₂/O₂ (98%/2%) microwave plasma etching, 2.6 KW, 170 mbar, 780 °C surface temperature, in a cavity reactor for 1 hour.

CH₄/H₂/O₂ gas mixture. [CH₄]=2.6% and [O₂]=3%. The gas mixture is injected at a flow rate of 50 SCCM for the duration of the synthesis.

Microwave power per source: 190 W.

Pressure: 0.35 mbar.

Substrate holder position (relative to microwave sources): 10 cm.

Solid substrate temperature: 750 °C.

Synthesis time: approx. 10 hours. Steps b) and c) are carried out simultaneously.

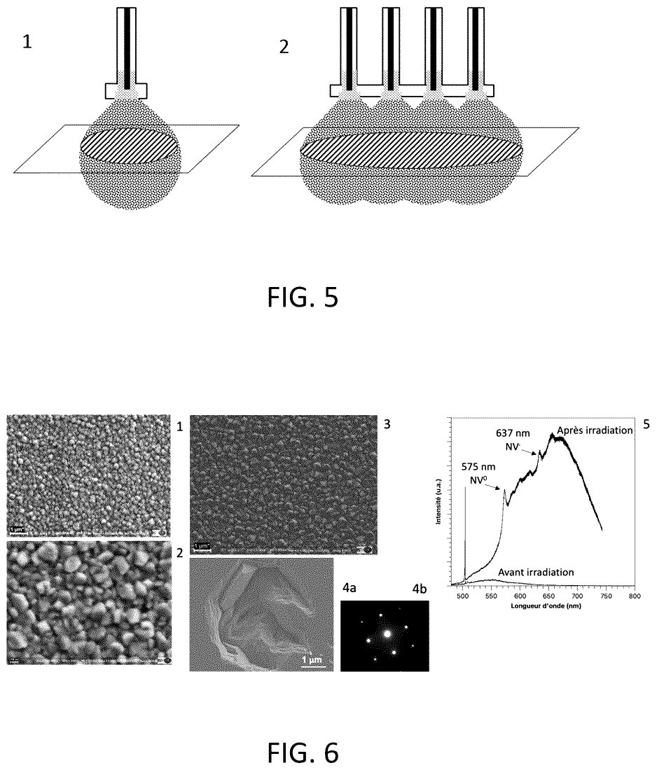

### 5. Synthesis of Nitrogen-Doped Single-Crystal Diamond Films for the Creation of Nitrogen-Vacancy (NV) Color Centers (FIG. 6-5)

Intrinsic CVD solid diamond substrate 50 μm thick deposited on a high-pressure high-temperature (HPHT) Ib substrate.

Solid substrate preparation: H₂/O₂ (98%/2%) microwave plasma etching, 2.6 kW, 170 mbar, 780 °C surface temperature, in a cavity reactor for 1 hour.

CH₄/H₂/O₂/N₂ gas mixture. [CH₄]=2.6%, [O₂]=3% and [N₂] =0.04%. The gas mixture is injected at a flow rate of 50 SCCM for the duration of the synthesis.

Microwave power per source: 190 W.

Pressure: 0.35 mbar.

Substrate holder position (relative to microwave sources): 10 cm.

Solid substrate temperature: 750 °C.

Synthesis time: approx. 10 hours. Steps b) and c) are carried out simultaneously.

The concentration of nitrogen atoms measured by SIMS (secondary ion mass spectrometry) is 1.5×10¹⁹ atoms/cm³ in a single-crystal diamond layer 3 μm thick. The creation of the NV centers is completed by irradiating the sample with a 200 keV electron beam for a dose of 1018 electrons/cm².

Nanocrystalline and microcrystalline diamond films can be used as hard and protective coatings, polycrystalline diamond films can be aftertreated, such as polished and cut, in order to design optical windows and heat sinks, intrinsic single-crystal diamond films can be used as encapsulation layers, and single-crystal diamond films containing NV centers can be used to design ultrasensitive magnetometers.

1-11. (canceled)

12. A method for coating at least one solid substrate with a synthetic diamond coating, comprising the steps of:
a) placing the at least one solid substrate on a substrate holder, inside a reaction chamber comprising a non-resonant cavity;
b) injecting a gas mixture into the chamber;
c) ionizing the gas mixture by subjecting the gas mixture to a microwave electromagnetic field, the microwave frequency ranging from 300 MHz to 6 GHz; and
forming a diamond coating layer on the at least one solid substrate, characterized in that,
the gas mixture consists of methane, dihydrogen, a third gas comprising at least one oxygen atom, and optionally a gaseous precursor of a doping element or reactivity modifier of the gas phase,
the CH₄/H₂ volume ratio ranges from 0.1 to 10%,
the third gas/CH₄ volume ratio ranges from 0.1 to 120%,
the temperature of the solid substrate is regulated to a value in a range from 100 to 1000 °C during the step of forming the diamond coating layer,
the pressure inside the reaction chamber is maintained in a range from 10⁻² to 100 mbar,
the microwave electromagnetic field being generated by means of a set of microwave sources.

13. The method as claimed in claim 12, further comprising one or more steps of preparing the surface of the solid substrate.

14. The method as claimed in claim 12, wherein steps b) and c) are repeated a number of iterations n, n being an integer greater than or equal to 2, preferably 2≤n≤10,so as to form a series of diamond coating layers on the solid substrate, the gas mixture being identical or different at each iteration.

15. The method as claimed in claim 12, wherein the solid substrate is composite or non-composite, and preferably composed of silicon, diamond, refractory metal or derivatives thereof, transition metal or derivatives thereof, stainless steel, a superalloy, a cemented carbide, a polymer, a ceramic, a glass, a selected oxide, a semiconductor selected from the semiconductors of columns III-V and II-VI of the periodic table, a piezoelectric material, a nitride, a carbide, a sulfide, a silicide or a mixture thereof.

16. The method as claimed in claim 12, wherein the thermal contact between the at least one solid substrate and the substrate holder is homogeneous over the entire contact surface between the at least one substrate and the substrate holder.

17. The method as claimed in claim 12, wherein the temperature of the solid substrate is regulated by convection and/or thermal conduction through the substrate holder.

18. The method as claimed in claim 12, wherein the substrate holder is electrically isolated from the cavity of the reaction chamber.

19. The method as claimed in claim 18, wherein the substrate holder is biased.

20. The method as claimed in claim 12, wherein the distance between the at least one solid substrate and a microwave source is in a range from 0.1 cm to 15 cm, preferably 10 cm.

21. A solid substrate comprising one or more diamond layers, obtained according to the method as claimed in claim 12.

22. A device comprising a solid substrate as claimed in claim 12, said device being selected from hard and protective coatings for cutting and perforating tools, glasses, optics, windows, scalpels, biocompatible coatings for implantable medical devices such as prostheses, dental implants, intracerebral electrodes and electronic devices such as surface acoustic wave or guided acoustic wave devices, sensors, components for power electronics, heat sinks for electronic and optoelectronic components, encapsulated electronic devices and quantum sensors such as ultrasensitive magnetometers.
